(19) United States
(12) Patent Application Publication
(10) Pub. No.: US 2011/0031005 A1
(43) Pub. Date: Feb. 10, 2011

(54) Cable structure

(76) Inventor: Mao-Chia Chou, Jhonghe City (TW)

Correspondence Address: PRO-TECHTOR INTERNATIONAL SERVICES, 20775 NORADA CT., SARATOGA, CA, 95070, US

(21) Appl. No.: 12/806,420

(22) Filed: Aug. 11, 2010

(30) Foreign Application Priority Data
Aug. 10, 2009 (TW) 098214670

(51) Int. Cl. H05K 9/00

(52) U.S. Cl. 174/350

(57) ABSTRACT

The present invention discloses a new cable structure. At an exterior of a central conductor, an insulation material and an EM wave resistant material are performed with insulation molding simultaneously, through forming equipment. This new cable structure changes the conventional cable structure, simplifies the way of processing, improves an electricity transmission feature and reduces utilization of materials, thereby not only achieving a market demand for a high transmission speed, but also fulfilling a goal of energy saving and reduction of CO₂ release.

### BACKGROUND OF THE INVENTION

a) Field of the Invention

The present invention relates to a cable structure, and more particularly to a cable which is provided with convenience of one time processing, a high speed transmission property and a feature of preventing from EM (electromagnetic) wave interference.

b) Description of the Prior Art

Referring to FIG. 1, a conventional cable includes plural conductors 100, exteriors of which are enclosed by a layer of insulation material 101. Referring to FIG. 2, the aforementioned cable is manufactured by first feeding in the conductors 100, performing insulation molding to the insulation material 101 through forming equipment and then assembling the cable with a connector to form an ordinary transmission line product. When assembling this cable, as an IDC (Insulation Displacement Connector) is used in processing without peeling off an insulative plastic cladding, and only one extrusion process is needed for manufacturing, assembling will be rather easy. However, the high frequency transmission property of that cable is inferior and the cable is not provided with the function of isolating from the EM wave.

Accordingly, there are vendors who have developed a cable as shown in FIG. 3, wherein an exterior of a single-wire conductor 200 is enclosed by a layer of insulation material 201, or another cable as shown in FIG. 4, wherein an exterior of a dual-wire conductor 300 is enclosed by a layer of insulation material 301, or another cable as shown in FIG. 5, wherein an exterior of a single-wire conductor 400 is enclosed by an inner layer of insulation material 401 with a better high frequency transmission property, and the inner insulation material 401 is enclosed by an outer layer of insulation material 402 with a stronger mechanical intensity.

The aforementioned three different cables can be assembled respectively as cable structures depending upon all kinds of requirements, as shown in FIGS. 6 to 9. To facilitate disclosure, the following descriptions are for the cable of the single-wire conductor 200 that is enclosed by the insulation layer 201, as shown in FIG. 3.

Referring to FIG. 6, two sets of single-wire conductors 200 are enclosed by the insulation material 201, with two sides being provided with two grounds 202, followed by being enclosed by a metal isolation layer 500.

Referring to FIG. 7, two sets of single-wire conductors 200 are enclosed by the insulation material 201 and then enclosed by the metal isolation layer 500, followed by providing two grounds 202 at the sides of the metal isolation layer 500.

Referring to FIG. 8, two sets of single-wire conductors 200 are enclosed by the insulation material 201 with one ground 202 being provided between the conductors 200, followed by being enclosed by the metal isolation layer 500.

Referring to FIG. 9, plural sets of single-wire conductors 200 are connected serially and then enclosed by the metal isolation layer 500.

Referring to FIG. 10, the manufacturing method of the aforementioned cables is first feeding in the conductors 200, 300, 400, performing the insulation molding to the insulation materials 201, 301, 401, 402 through the forming equipment, providing a layer of shielding tape through taping equipment, performing outer insulation molding to the metal isolation layer 500 through the forming equipment, processing with the IDCs after forming the cables, peeling off the outer insulation and the metal isolation layer 500 of the shielding tape, and finally assembling the cables with the connectors as the transmission line products. As the manufacturing process of the aforementioned cables is more complex and the post-assembly of the cables is also more complex that the succeeding procedure of processing the connectors can be only done after peeling off the metal isolation layer, improvement is required.

### SUMMARY OF THE INVENTION

It is therefore the primary object of the present invention to provide a cable structure, wherein at an exterior of a central conductor of a new cable, an insulation material and a new EM wave resistant material are performed simultaneously with insulation molding through forming equipment. This new cable can be manufactured and assembled easily; in addition, it is also provided with a good high frequency transmission property and a feature of preventing from the EM wave interference.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a planar view of a conventional cable structure.

FIG. 2 shows a flow diagram of a conventional cable structure.

FIG. 3 shows a schematic view of a conventional simplex cable.

FIG. 4 shows a schematic view of a conventional duplex cable.

FIG. 5 shows a schematic view of another conventional simplex cable.

FIG. 6 shows a first schematic view of assembly of a conventional simplex cable.

FIG. 7 shows a second schematic view of assembly of a conventional simplex cable.

FIG. 8 shows a third schematic view of assembly of a conventional simplex cable.

FIG. 9 shows a fourth schematic view of assembly of a conventional simplex cable.

FIG. 10 shows a flow diagram of a manufacturing process for assembling and forming a conventional cable.

FIG. 11 shows a planar view of a cable structure according to the present invention.

FIG. 12 shows a flow diagram of the cable structure according to the present invention.

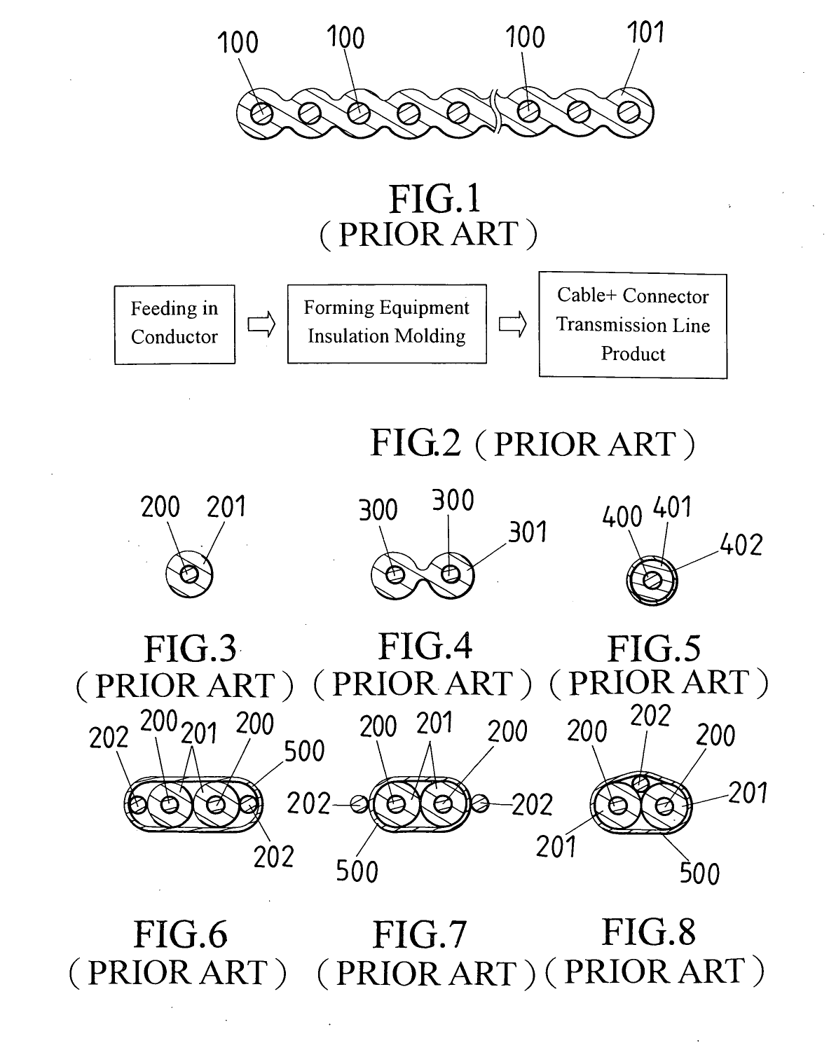

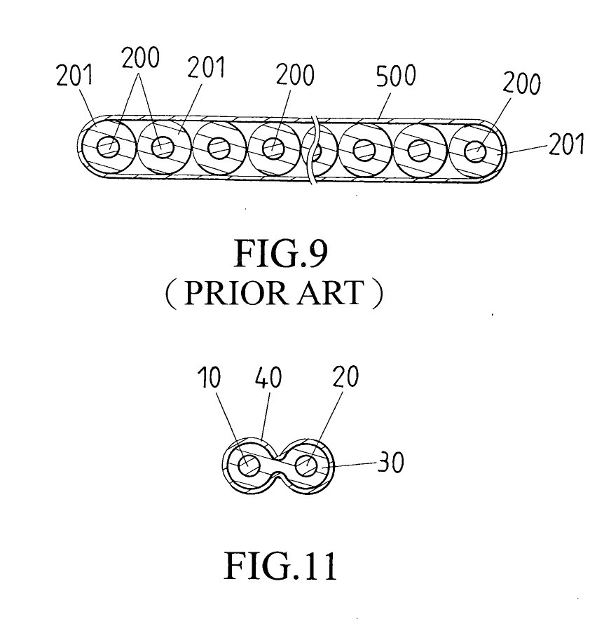

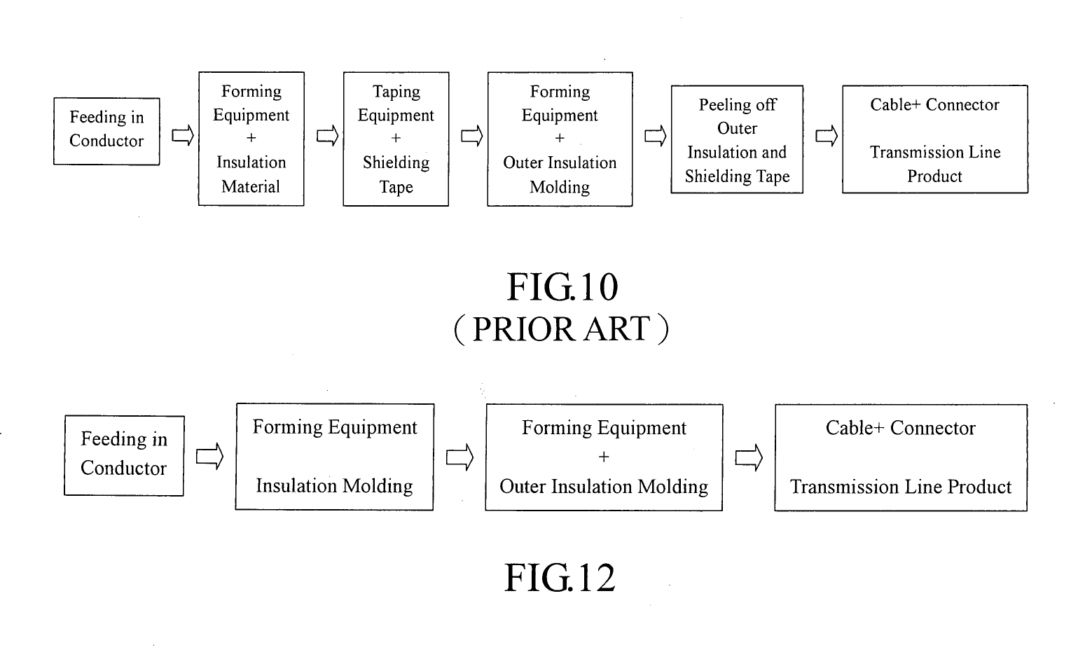

### DETAILED DESCRIPTION OF THE PREFERRED EMBODIMENTS

Referring to FIG. 11, the cable structure of the present invention comprises two central conductors 10, 20, wherein at exteriors of the conductors 10, 20, an insulation material 30 and a new EM wave resistant material 40 are performed simultaneously with insulation molding, through forming equipment, allowing that the two central conductors 10, 20 are enclosed by the layer of insulation material 30 and the layer of new EM wave resistant material 40, so as to form the new cable.

Referring to FIG. 12, the manufacturing method of the aforementioned cable is first feeding in the central conductors 10, 20 of two simplex cables which are processed one time, performing the insulation molding simultaneously to the insulation material 30 and the new EM wave resistant material 40 through the forming equipment, and finally assembling the cable with the connector to form a new transmission line product.

As the present invention utilizes a different mold design that by only through an extrusion process once, an insulation material, which is provided with a high frequency transmission property, like an inner insulation layer in the prior art, and a stronger mechanical intensity, like an outer insulation layer in the prior art, can be accomplished. Moreover, as the conventional metal isolation layer is replaced by the new EM wave resistant material 40, the function of isolating from the EM wave can be achieved as well. Besides, as the EM wave resistant material 40 is an insulation material, a simple processing method for the convention cable can be used that the manufacturing of the cable can be accomplished. In addition, the shortcomings of the prior art that the high frequency transmission performance and the resistance to EM wave interference are inferior, the cable manufacturing speed is slow, as well as the post-assembly of cable is difficult, can be eliminated.

Accordingly, the present invention provides a new cable structure with a good high frequency transmission performance and better resistance to EM wave interference, which can be accomplished by performing an extrusion process once. This new cable structure changes the conventional cable structure, simplifies the way of processing, improves the electricity transmission feature and reduces utilization of materials, thereby not only achieving a market demand for a high transmission speed, but also fulfilling a goal of energy saving and reduction of CO₂ release.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A cable structure comprising a central conductor, wherein an exterior of the central conductor is orderly provided with an insulation material and an EM wave resistant material, the central conductor is first enclosed by the layer of insulation material through forming equipment, and then the insulation material is enclosed by the layer of EM wave resistant material, with the two layers of materials being performed with insulation molding at a same time.
